(19) United States
(12) Patent Application Publication
(10) Pub. No.: US 2026/0132503 A1
(43) Pub. Date: May 14, 2026

(54) OXYGEN-NITROGEN CO-DOPED HOLLOW CARBON NANOPARTICLE AND PREPARATION METHOD THEREFOR AND APPLICATION IN ELECTROSYNTHESIS OF HYDROGEN PEROXIDE

(71) Applicant: Zhejiang Epai Technology Co., Ltd, Hangzhou (CN)

(72) Inventors: Weikai Xiang, Hangzhou (CN); Xiaoqin Ye, Hangzhou (CN); Luping Zhang, Hangzhou (CN); Chunru Liu, Hangzhou (CN); Luowei Pei, Hangzhou (CN)

(21) Appl. No.: 19/385,912

(22) Filed: Nov. 11, 2025

(30) Foreign Application Priority Data
Nov. 12, 2024 (CN) 202411603601.1

(51) Int. Cl. C23C 16/44; C09C 1/56; C23C 16/28; C25B 11/043

(52) U.S. Cl. CPC C23C 16/4417; C09C 1/56; C23C 16/28; C25B 11/043; C01P 2002/52; C01P 2002/85; C01P 2004/04; C01P 2004/62; C01P 2004/64; C01P 2004/86; C01P 2006/40

(57) ABSTRACT

An oxygen-nitrogen co-doped hollow carbon nanoparticle and a preparation method therefor and an application for electrosynthesis of hydrogen peroxide. Carbon nanoparticles are taken as a base material, firstly, in an oxygen-containing atmosphere, high-energy oxygen plasma generated by radio frequency (RF) excitation bombard the surface of the carbon nanoparticles, forcing carbon-carbon bonds in the carbon material to break and exerting a strong ablation effect on graphite layers of carbon, thereby forming a special hollow carbon structure. After an oxygen doping reaction is finished, the oxygen-containing atmosphere is switched to a nitrogen-containing atmosphere to prepare an oxygen-nitrogen co-doped hollow carbon nanoparticle catalyst.

### CROSS-REFERENCE TO RELATED APPLICATION

This application claims priority of Chinese Patent Application No. 202411603601.1, filed on Nov. 12, 2024, the entire contents of which are incorporated herein by reference.

### TECHNICAL FIELD

The present disclosure relates to the technical field of electrocatalysis, and in particular to an oxygen-nitrogen co-doped hollow carbon nanoparticle, a preparation method therefor and an application in electrosynthesis of hydrogen peroxide.

### BACKGROUND

Hydrogen peroxide is one of the hundred most important chemicals in the world, which is widely used in various fields including chemical synthesis, water treatment, bleaching and disinfection. In the synthesis method of hydrogen peroxide, the energy-saving and environmentally friendly electrocatalytic two-electron oxygen reduction technology for synthesizing hydrogen peroxide is considered to be an effective way to replace the traditional anthraquinone process with high energy consumption and high pollution. To meet the economic feasibility of industrial production, the electrosynthesis process of hydrogen peroxide needs to operate at high current density (>100 mA/cm²), while maintaining high hydrogen peroxide selectivity and long life. Therefore, one of the core issues of electrosynthesis of hydrogen peroxide technology is the development of high-performance oxygen reduction catalysts, which fundamentally determines the energy efficiency and economy of the whole electrolysis process.

A large number of studies have shown that cheap carbon materials are a feasible catalyst for hydrogen peroxide production via oxygen reduction and have good catalytic performance. Improving the specific surface area of the catalyst, i.e. increasing the number of exposed active sites, is the simplest and most efficient solution to strengthen the electrocatalytic activity. For example, the Chinese patent CN117431559A provides a highly selective carbon-based catalyst for electrochemical synthesis of H₂O₂ and a preparation method and an application. In this disclosure, mesoporous carbon with high specific surface area is selected as the raw material for catalytic modification. To further enhance the intrinsic electrocatalytic activity, a commonly feasible method is to introduce non-metallic heteroatoms on the carbon surface, including oxygen, nitrogen and boron, which enables to adjust the electronic structure of adjacent carbon atoms, optimize the adsorption energy of key oxygen species (*OOH) intermediates in the oxygen reduction reaction, and improve the catalytic activity and selectivity of carbon materials (Nano-MicroLetters.2023, 15, 122). For example, the Chinese patent CN115852424A provides an application of an oxygen-doped carbon material in electrocatalytic synthesis of hydrogen peroxide, and the Chinese patent CN117144395A3 provides a preparation method and an application of a boron/nitrogen co-doped carbon catalyst for electrocatalytic synthesis of hydrogen peroxide. The performance of electrosynthesis of hydrogen peroxide of the carbon materials reported above is significantly improved after doping modification. However, the doping method used is complex and time-consuming (about 15 h), and it also requires the use of high-temperature (400-900° C.) high-pressure environment and highly corrosive acid reagents, which is not conducive to environmental protection and the promotion of industrial production. To solve the above problems, the Chinese patent CN117926285A provides a plasma oxygen doped activated carbon catalyst, a preparation method and an application therefor. In this disclosure, high-energy oxygen plasma is used as reactant, a series of oxygen-doped activated carbon catalysts are prepared at room temperature by adjusting reaction time (10-40 min) and reaction power (100-300 W). Although this method can improve the selectivity of hydrogen peroxide to a certain extent, the improvement of electrocatalytic activity is quite limited.

### SUMMARY

An objective of the present disclosure is to provide an oxygen-nitrogen co-doped hollow carbon nanoparticle and a preparation method therefor and an application for electrosynthesis of hydrogen peroxide. The oxygen-nitrogen co-doped hollow carbon nanoparticle has excellent two-electron oxygen reduction electrocatalytic activity, hydrogen peroxide selectivity and stability.

To achieve the above objective, the present disclosure provides the following technical solutions.

The present disclosure provides a preparation method for an oxygen-nitrogen co-doped hollow carbon nanoparticle, including the steps of:
adopting a plasma-enhanced chemical vapor deposition (PECVD) method:
performing a first deposition on carbon nanoparticles in an oxygen-containing atmosphere, and obtaining oxygen-doped hollow carbon nanoparticles through ablation effect of oxygen-containing plasma; and
performing a second deposition on the oxygen-doped hollow carbon nanoparticles in a nitrogen-containing atmosphere to obtain oxygen-nitrogen co-doped hollow carbon nanoparticles, in which
a surface graphite layer of the oxygen-nitrogen co-doped hollow carbon nanoparticles has a thickness of 5-100 atomic layers, and a cavity width of 5-50 nm;
in the oxygen-nitrogen co-doped hollow carbon nanoparticles, a molar content of doped oxygen atoms is 1-12%, and a molar content of carbonyl oxygen atoms in the doped oxygen atoms in the oxygen-nitrogen co-doped hollow carbon nanoparticles is 0.5-3%; and the carbonyl oxygen has an X-ray photoelectron spectroscopy (XPS) binding energy (BE) BE=531.0 eV;
a content x of the carbonyl oxygen atoms and an electrocatalytic activity y satisfy following functional relationship: y=0.058x+0.61, with R²=0.90; where y is calculated by a half-wave potential E_{1/2} in volts (V) versus (vs.) a reversible hydrogen electrode (RHE); and
in the oxygen-nitrogen co-doped hollow carbon nanoparticles, a molar content of doped nitrogen atoms is 14%, a molar percentage of pyridine nitrogen and pyrrole nitrogen in the doped nitrogen atoms is 50-80%, and a molar ratio of the pyridine nitrogen and the pyrrole nitrogen is 0.5:1-2:1.

Further, the carbon nanoparticles are conductive carbon black, and a particle size of the conductive carbon black is 10-200 nm.

Further, the oxygen-containing atmosphere includes one or more of oxygen-argon, carbon dioxide-argon, or water vapor-argon.

Further, a volume fraction of argon in the oxygen-containing atmosphere is 50-90%; and a flow rate of the oxygen-containing atmosphere is 20-200 mL/min.

Further, the surface graphite layer thickness of the oxygen-nitrogen co-doped hollow carbon nanoparticles is 5-100 atomic layers, and a cavity width is 5-50 nm.

Further, the nitrogen-containing atmosphere includes nitrogen or ammonia; and a flow rate of the nitrogen-containing atmosphere is 20-200 mL/min.

Further, conditions of the first deposition and the second deposition independently include: plasma radio frequency (RF) power of 100-500 W, vacuum degree of 10-100 Pa, sample tube rotation speed of 50-100 rpm, temperature of 25-500° C., and time of 10-60 min.

The present disclosure provides the oxygen-nitrogen co-doped hollow carbon nanoparticle prepared by the preparation method of the technical solution.

The present disclosure provides an application of the oxygen-nitrogen co-doped hollow carbon nanoparticle in electrosynthesis of hydrogen peroxide.

The present disclosure provides a preparation method for the oxygen-nitrogen co-doped hollow carbon nanoparticle. In the present disclosure, a PECVD method is adopted, and a carbon material is used as a base material. Firstly, in the oxygen-containing atmosphere, high-energy plasma generated by RF excitation bombard the surface of the carbon material, forcing the carbon-carbon bond in the carbon material to break, and generating a strong ablation effect on the graphite layer of carbon, thereby forming a hollow carbon structure with a high specific surface area, which can greatly improve the effective electrocatalytic specific surface area. Moreover, a large number of oxygen atoms can be introduced during the ablation of graphite layer, and the geometric configuration of oxygen atoms can be adjusted by reaction temperature and the type of excited atmosphere, thereby obtaining oxygen-doped hollow carbon nanoparticles with excellent electrocatalytic performance. After the oxygen doping reaction is finished, the oxygen-containing atmosphere is switched to the nitrogen-containing atmosphere to prepare an oxygen-nitrogen co-doped hollow carbon nanoparticle catalyst, which can be used for electrocatalytic synthesis of hydrogen peroxide. The oxygen-nitrogen co-doped hollow carbon nanoparticles prepared by the present disclosure not only improve the selectivity of hydrogen peroxide, but also greatly improve the electrocatalytic activity (the half-wave potential is reduced by about 100 mV). This is due to the following reasons: firstly, the prepared carbon nano-materials are hollow, which greatly increases the active area of the catalyst, indicating an increase in the number of active sites involved in the catalytic reaction, and facilitating the mass transfer process of the reaction; and secondly, oxygen and nitrogen doping can optimize intrinsic catalytic performance of the carbon nanoparticle and accelerate the reaction kinetics.

In the present disclosure, by changing the process parameters (gas source type, temperature and power), the morphology characteristics of carbon nanoparticles can be regulated and the geometric configuration of oxygen and nitrogen atoms on the carbon surface can be introduced, thereby greatly improving the electrocatalytic oxygen reduction reaction activity and hydrogen peroxide selectivity of the carbon nanoparticle, and obtaining high-performance oxygen-nitrogen co-doped hollow carbon nanoparticles.

The preparation method of the present disclosure is simple, efficient and environmentally friendly, and is beneficial to industrial production.

The oxygen-nitrogen co-doped hollow carbon nanoparticles prepared by the present disclosure can stably run for more than 100 hours under a high current density (such as 300 mA/cm²), can maintain a current efficiency of 90-100%, and have excellent two-electron oxygen reduction electrocatalytic activity, hydrogen peroxide selectivity and stability.

In the present disclosure, the PECVD method is used to adjust a proportion of introduced oxygen atoms to further optimize the activity and selectivity of electrocatalytic oxygen reduction of carbon materials, and at the same time, the PECVD method is used to accurately regulate the geometric configuration of oxygen-nitrogen doping, thereby realizing controllable oxygen-nitrogen doping, and optimizing the intrinsic catalytic performance of the carbon nano-materials.

### BRIEF DESCRIPTION OF THE DRAWINGS

FIG. 1A shows oxygen reduction polarization curves of different carbon materials.

FIG. 1B shows hydrogen peroxide selectivity curves of different carbon materials.

FIG. 2A shows a transmission electron microscopy (TEM) image of a modified carbon material prepared from initial carbon.

FIG. 2B shows a TEM image of the modified carbon material prepared in Example 6.

FIG. 2C shows a TEM image of the modified carbon material prepared in Example 16.

FIG. 2D shows a TEM image of the modified carbon material prepared in Example 18.

FIG. 3 shows an electrical double-layer capacitance diagram of different carbon materials.

FIG. 4 shows high-resolution Ols (oxygen is orbital electron) XPS spectra of different carbon materials.

FIG. 5 shows a relationship diagram between carbonyl content and electrocatalytic activity of an initial carbon material and oxygen-doped carbon materials prepared in Examples 1-9.

FIG. 6 shows high-resolution N1s (nitrogen is orbital electron) XPS spectra of different carbon materials.

FIG. 7A shows a O1s spectra of oxygen-nitrogen co-doped hollow carbon nanoparticles prepared in Example 16.

FIG. 7B shows a Nis spectra of the oxygen-nitrogen co-doped hollow carbon nanoparticles prepared in Example 16.

FIG. 8 shows a graph of cell voltage and hydrogen peroxide selectivity versus time in the oxygen-nitrogen co-doped hollow carbon nanoparticles prepared in Example 16.

FIG. 9 is a schematic diagram of a preparation flow of the oxygen-nitrogen co-doped hollow carbon nanoparticles of the present disclosure.

### DETAILED DESCRIPTION

In the present disclosure, unless otherwise specified, raw materials or reagents necessary for preparation are commercially available products well known to those skilled in the art.

The present disclosure provides a preparation method for an oxygen-nitrogen co-doped hollow carbon nanoparticle, including the following steps.

A PECVD method is adopted.

A first deposition is performed on carbon nanoparticles in an oxygen-containing atmosphere, and oxygen-doped hollow carbon nanoparticles are obtained through ablation effect of oxygen-containing plasma.

A second deposition is performed on the oxygen-doped hollow carbon nanoparticles in a nitrogen-containing atmosphere to obtain oxygen-nitrogen co-doped hollow carbon nanoparticles.

A surface graphite layer of the oxygen-nitrogen co-doped hollow carbon nanoparticles has a thickness of 5-100 atomic layers, and a cavity width of 5-50 nm.

In the oxygen-nitrogen co-doped hollow carbon nanoparticles, a molar content of doped oxygen atoms is 1-12%, and a molar content of carbonyl oxygen atoms in the doped oxygen atoms in the oxygen-nitrogen co-doped hollow carbon nanoparticles is 0.5-3%; and the carbonyl oxygen has an XPS binding energy BE=531.0 eV

A content x of the carbonyl oxygen atoms and an electrocatalytic activity y satisfy the following functional relationship: y=0.058x+0.61, with R²=0.90; where y is calculated by a half-wave potential E_{1/2}V vs. RITE.

In the oxygen-nitrogen co-doped hollow carbon nanoparticles, a molar content of doped nitrogen atoms is 14%, a molar percentage of pyridine nitrogen and pyrrole nitrogen in the doped nitrogen atoms is 50-80%, and a molar ratio of the pyridine nitrogen and the pyrrole nitrogen is 0.5-2:1.

In the present disclosure, the carbon nanoparticles are preferably conductive carbon black, and a particle size of the conductive carbon black is preferably 10-200 nm. In the present disclosure, the source of the conductive carbon black is not particularly limited, and commercial conductive carbon blacks well known in the art may be used.

In the present disclosure, the amount of the carbon nanoparticles used is not particularly limited, but is adjusted according to actual needs, and the amount of the carbon nanoparticles added in a single batch is more preferably 1-10 g.

In the present disclosure, the oxygen-containing atmosphere preferably includes one or more of oxygen-argon, carbon dioxide-argon, or water vapor-argon. When the oxygen-containing atmosphere is two or more of the above options, it is preferable to adjust and ensure the oxygen content of the oxygen-containing atmosphere according to actual needs.

In the present disclosure, a volume fraction of argon in the oxygen-containing atmosphere is preferably 50-90%, and more preferably 60-80%. A flow rate of the oxygen-containing atmosphere is preferably 20-200 mL/min, and more preferably 100−150 mL/min.

In the present disclosure, conditions of the first deposition preferably include: plasma RF power of 100-500 W, vacuum degree of 10-100 Pa, sample tube rotation speed of 50-100 rpm (revolutions per minute), temperature of 25-500° C., and time of 10-60 minutes. The plasma RF power is more preferably 100-200 W, the vacuum degree is more preferably 40-60 Pa, the sample tube rotation speed is more preferably 60-80 rpm, the temperature is more preferably 100-300° C., and the time is more preferably 20-40 min. A temperature rise rate to the temperature of the first deposition is preferably 10° C./min.

In the present disclosure, the surface graphite layer of the oxygen-nitrogen co-doped hollow carbon nanoparticles has a thickness of 5-100 atomic layers, and a cavity width of 5-50 nm.

In the present disclosure, a solid commercial carbon material is used as a base material. In oxygen-containing atmosphere, RF excitation is performed on the carbon material by PECVD to generate super-oxidizing oxygen-containing plasma that is used to ablate the graphite layer in the carbon, and oxygen atoms are introduced into the graphite layer of the carbon in an ablation process of the graphite layer to obtain oxygen-doped hollow carbon nanoparticles with specific morphology.

In the present disclosure, the nitrogen-containing atmosphere preferably includes nitrogen or ammonia; and a flow rate of the nitrogen-containing atmosphere is preferably 20-200 mL/min, more preferably 50-150 mL/min, and further preferably 60-120 mL/min.

In the present disclosure, conditions of the second deposition preferably include plasma RF power of 100-500 W, vacuum degree of 10-100 Pa, sample tube rotation speed of 50-100 rpm, temperature of 25-500° C., and time of 10-60 min. The plasma RF power is more preferably 100-200 W, the vacuum degree is more preferably 40-60 Pa, further preferably 50 Pa, the sample tube rotation speed is more preferably 60-80 rpm, the temperature is more preferably 100-300° C., and the time is more preferably 20-40 min.

In the present disclosure, the oxygen-doped hollow carbon nanoparticles are reacted with nitrogen plasma excited by PECVD through the second deposition. Oxygen-nitrogen co-doped hollow carbon nanoparticles with adjustable ratios of pyridine nitrogen and pyrrole nitrogen are prepared by controlling the reaction temperature.

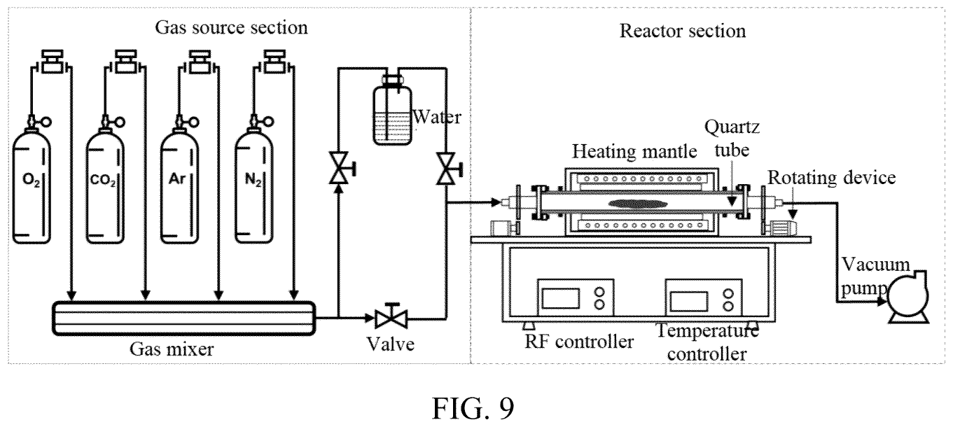

As shown in FIG. 9, in the present disclosure, preferably, the carbon material is placed in a quartz tube reactor, and oxygen-containing gas is continuously introduced; a vacuum pump is turned on to evacuate the quartz tube reactor to the required vacuum degree; the quartz tube reactor is heated to the reaction temperature, and the plasma RF power supply is turned on; after the reaction performed for a specific time, the RF power supply is turned off, after naturally cooling the quartz tube reactor to room temperature, the vacuum pump and gas flow are turned off; and the material inside the quartz tube reactor is collected. To ensure the uniformity of carbon material modification, the quartz tube reactor is kept rotating continuously during the reaction.

The present disclosure provides the oxygen-nitrogen co-doped hollow carbon nanoparticle prepared by the preparation method of the above technical solution.

In the present disclosure, in the oxygen-nitrogen co-doped hollow carbon nanoparticles, a molar content of doped oxygen atoms is 1-12%, and preferably 6-10%; and a molar content of carbonyl oxygen atoms in the doped oxygen atoms in the oxygen-nitrogen co-doped hollow carbon nanoparticles is 0.5-3%, and preferably 2 to 3%; and the carbonyl oxygen has an XPS BE (binding energy) of 531.0 eV.

In the present disclosure, a content x of the carbonyl oxygen atoms and an electrocatalytic activity y satisfy the following functional relationship: y=0.058x+0.61, with R²=0.90; where y is calculated by a half-wave potential (E_{1/2}/V vs. RHE).

In the oxygen-nitrogen co-doped hollow carbon nanoparticles, a molar content of doped nitrogen atoms is 14%, preferably 2-3%, a molar percentage of pyridine nitrogen and pyrrole nitrogen in the doped nitrogen atoms is 50-80%, preferably 70-80%, and a molar ratio of pyridine nitrogen and pyrrole nitrogen is 0.5:1-2:1, preferably 1:1-1.5:1.

The present disclosure provides an application of the oxygen-nitrogen co-doped hollow carbon nanoparticle in electrosynthesis of hydrogen peroxide. The present disclosure is not particularly limited to the application method, and can be applied according to methods well known in the field.

The technical solutions provided by the present disclosure will be described in detail with examples below, which cannot be understood as limiting the protection scope of the present disclosure.

### EXAMPLES

The carbon black powder used in the following examples is a conductive carbon black with a particle size of 10-200 nm.

### 1. Oxygen-Doped Carbon Material

Three-factor and three-level orthogonal experiments are conducted to verify the effects of PECVD process parameters on the configuration of introduced oxygen atoms and catalyst performance:

$$factor 1 = atmosphere ( {O}_{2} / Ar , {CO}_{2} / Ar , and {H}_{2} O / Ar ) ;$$

$$factor 2 = temperature ( 25 ° C . , 100 ° C . , and 300 ° C . ) ;$$

$$and$$

$$factor 3 = power ( 100 W , 3 \; 00 W , and 500 W ) .$$

TABLE 1
Orthogonal experimental parameters of Examples 1-9

| Experiment number | Atmosphere | Temperature/° C. | Power/W |
|---|---|---|---|
| Example 1 | O₂/Ar | 25 | 100 |
| Example 2 | O₂/Ar | 100 | 500 |
| Example 3 | O₂/Ar | 300 | 300 |
| Example 4 | CO₂/Ar | 25 | 500 |
| Example 5 | CO₂/Ar | 100 | 300 |
| Example 6 | CO₂/Ar | 300 | 100 |
| Example 7 | H₂O/Ar | 25 | 300 |
| Example 8 | H₂O/Ar | 100 | 100 |
| Example 9 | H₂O/Ar | 300 | 500 |

### Example 1

In step 1), 10 g of carbon black powder (XC-72R, Cabot Company) is accurately weighed, the powder is placed in a quartz tube reactor (PECVD equipment model ZH-1000M), and the quartz tube reactor is kept rotating at a constant speed of 60 rpm.

In step 2), a mixed gas of oxygen and argon is continuously introduced (a volume fraction of argon is 50%) with a total gas flow rate of 100 mL/min; and a vacuum pump is turned on, and the quartz tube reactor is evacuated to a vacuum degree of 50 Pa.

In step 3), a plasma RF power supply is turned on, the reaction is performed at a RF power of 100 W for 10 min, and the RF power supply is turned off.

In step 4), the vacuum pump and a mixed gas flow control valve are turned off, an argon flushing mode is turned on to restore the quartz tube reactor to normal pressure (i.e., atmospheric pressure), and a reaction product is collected to obtain an oxygen-doped carbon material.

### Example 2

The difference from Example 1 is only that before starting step 3), the quartz tube reactor needs to be heated to 100° C., and the RF power used in step 3) is 500 W.

### Example 3

The difference from Example 1 is only that before starting step 3), the quartz tube reactor needs to be heated to 300° C., and the RF power used in step 3) is 300 W.

### Example 4

The difference from Example 1 is only that the mixed gas used in step 2) is carbon dioxide and argon (a volume fraction of argon is 50%), and the RF power used in step 3) is 500 W.

### Example 5

The difference from Example 1 is only that the mixed gas used in step 2) is carbon dioxide and argon (the volume fraction of argon is 50%); and before starting step 3), the quartz tube reactor needs to be heated to 100° C., and the RF power used in step 3) is 300 W.

### Example 6

The difference from Example 1 is only that the mixed gas used in step 2) is carbon dioxide and argon (the volume fraction of argon is 50%); and before starting step 3), the quartz tube reactor needs to be heated to 300° C., and the RF power used in step 3) is 100 W.

### Example 7

The difference from Example 1 is only that wet argon (argon flows through a gas-washing bottle to carry water vapor, and the volume fraction of argon is 50%) with a flow rate of 100 mL/min is used; and the RF power used in step 3) is 300 W.

### Example 8

The difference from Example 1 is only that wet argon (argon flows through a gas-washing bottle to carry water vapor, and the volume fraction of argon is 50%) with a flow rate of 100 mL/min is used; and before starting step 3), the quartz tube reactor needs to be heated to 100° C., and the RF power used in step 3) is 100 W.

### Example 9

The difference from Example 1 is only that wet argon (argon flows through a gas-washing bottle to carry water vapor, and the volume fraction of argon is 50%) with a flow rate of 100 mL/min is used; and before starting step 3), the quartz tube reactor needs to be heated to 300° C., and the RF power used in step 3) is 500 W.

### 2. Nitrogen-Doped Carbon Material

The effects of reaction temperature and RF power on the geometric configuration of introduced nitrogen atom and catalyst performance are studied with high-energy nitrogen plasma as nitrogen source:

### Example 10

In step 1), 10 g of carbon black powder (XC-72R, Cabot Company) is accurately weighed, the powder is placed in a quartz tube reactor (PECVD equipment model ZH-1000M), and the quartz tube reactor is kept rotating at a constant speed of 60 rpm.

In step 2), nitrogen gas is continuously introduced with a flow rate of 100 mL/min; and a vacuum pump was turned on, and the quartz tube reactor is evacuated to a vacuum degree of 50 Pa.

In step 3), a plasma RF power supply is turned on, the reaction is performed at a RF power of 100 W for 20 min, and the RF power supply is turned off.

In step 4), the vacuum pump and a mixed gas flow control valve are turned off, an argon flushing mode is turned on to restore the quartz tube reactor to normal pressure (i.e., atmospheric pressure), and a reaction product is collected to obtain a nitrogen-doped carbon material.

### Example 11

The difference from Example 10 is only that the RF power used in step 3) is 300 W.

### Example 12

The difference from Example 10 is only that the RF power used in step 3) is 500 W.

### Example 13

The difference from Example 10 is only that before starting step 3), the quartz tube reactor needs to be heated to 100° C., and the RF power used in step 3) is 100 W.

### Example 14

The difference from Example 10 is only that before starting step 3), the quartz tube reactor needs to be heated to 300° C., and the RF power used in step 3) is 100 W.

### 3. Oxygen/Nitrogen Co-Doped Carbon Material

### Example 15

In step 1), 10 g of carbon black powder (XC-72R, Cabot Company) is accurately weighed, the powder is placed in a quartz tube reactor (PECVD equipment model ZH-1000M), and the quartz tube reactor is kept rotating at a constant speed of 60 rpm.

In step 2), a mixed gas of carbon dioxide and argon is continuously introduced (a volume fraction of argon is 50%) with a flow rate of 100 mL/min; a tube furnace is heated to 300° C. at a heating rate of 10° C./min; and the vacuum pump is turned on, and the quartz tube reactor is evacuated to a vacuum degree of 50 Pa.

In step 3), a plasma RF power supply is turned on, the reaction is performed at a RF power of 100 W for 10 min, and the RF power supply and the tube furnace power supply are turned off.

In step 4), the mixed gas is switched to high-purity nitrogen (purity 99.99%) with a flow rate of 100 mL/min; and after the tube furnace is cooled to 25° C., the RF power supply is turned on, the reaction is performed at a vacuum degree of 50 Pa and a RF power of 100 W for 20 min, and the RF power is turned off.

In step 5), the vacuum pump and the gas flow control valve are turned off, and the argon flushing mode is turned on, the quartz tube reactor is restored to normal pressure (i.e., atmospheric pressure), and reaction products are collected to obtain oxygen-nitrogen co-doped hollow carbon nanoparticles. A molar content of doped oxygen atoms in the oxygen-nitrogen co-doped hollow carbon nanoparticles is 10.9%, and a molar content of carbonyl oxygen atoms in the oxygen-nitrogen co-doped hollow carbon nanoparticles is 2.1%; and a molar content of doped nitrogen atoms was 1.8%, a molar percentage of pyridine nitrogen and pyrrole nitrogen in the doped nitrogen atoms to the total nitrogen atoms is 68.9%, and a molar ratio of pyridine nitrogen to pyrrole nitrogen is 0.6:1.

### Example 16

In step 1), 10 g of carbon black (XC-72R, Cabot Company) is accurately weighed, the carbon black is placed in a quartz tube reactor (PECVD equipment model ZH-1000M), and the quartz tube reactor is kept rotating at a constant speed of 60 rpm.

In step 2), a mixed gas of carbon dioxide and argon is continuously introduced (a volume fraction of argon is 50%) with a flow rate of 100 mL/min; a tube furnace is heated to 300° C. at a heating rate of 10° C./min; and the vacuum pump is turned on, and the quartz tube reactor is evacuated to a vacuum degree of 50 Pa.

In step 3), a plasma RF power supply is turned on, the reaction is performed at a RF power of 100 W for 10 min, and the RF power supply is turned off.

In step 4), the mixed gas is switched to high-purity nitrogen (purity 99.99%) with a flow rate of 100 mL/min; after waiting for 10 min (until the carbon dioxide and argon in the quartz tube reactor are completely discharged), the RF power supply is turned on, the reaction is performed at a vacuum degree of 50 Pa, temperature of 300° C., and a RF power of 100 W for 20 min, and the RF power supply is turned off.

In step 5), after the quartz tube reactor and RF electrode are naturally cooled to room temperature, the vacuum pump and gas flow control valve are turned off, the argon flushing mode is turned on to restore the quartz tube reactor to normal pressure (i.e., atmospheric pressure), and reaction products are collected to obtain oxygen-nitrogen co-doped hollow carbon nanoparticles. The molar content of doped oxygen atoms is 10.1%, and a molar content of carbonyl oxygen atoms in the oxygen-nitrogen co-doped hollow carbon nanoparticles is 2.3%; and a molar content of doped nitrogen atoms is 2.1%, a molar percentage of pyridine nitrogen and pyrrole nitrogen in the doped nitrogen atoms to the total nitrogen atoms is 75.2%, and a molar ratio of pyridine nitrogen and pyrrole nitrogen is 1.5:1.

### Example 17

The difference from Example 16 is only that in step 3), the oxygen-nitrogen co-doped hollow carbon nanoparticles is prepared by reacting at 100 W RF power for 20 min, the molar content of doped oxygen atoms is 11.2%, and the molar content of carbonyl oxygen atoms in the oxygen-nitrogen co-doped hollow carbon nanoparticles is 2.4%; and the molar content of doped nitrogen atoms is 2.3%, the molar percentage of pyridine nitrogen and pyrrole nitrogen in the doped nitrogen atoms to the total nitrogen atoms is 76.7%, and the molar ratio of pyridine nitrogen and pyrrole nitrogen is 1.4:1.

### Example 18

The difference from Example 16 is only that in step 3), the oxygen-nitrogen co-doped hollow carbon nanoparticles is prepared by reacting at 100 W RF power for 40 min, the molar content of doped oxygen atoms is 11.6%, and the molar content of carbonyl oxygen atoms in the oxygen-nitrogen co-doped hollow carbon nanoparticles is 2.3%; and the molar content of doped nitrogen atoms is 1.9%, the molar percentage of pyridine nitrogen and pyrrole nitrogen in the doped nitrogen atoms to the total nitrogen atoms is 74.9%, and the molar ratio of pyridine nitrogen to pyrrole nitrogen is 1.6:1.

### Test of Catalytic Performance

The carbon materials prepared in different Examples are used as catalysts to test the catalytic performance thereof.

### 1. Three-Electrode Rotating Ring-Disk Electrode (RRDE) Test (for Evaluating Intrinsic Electrocatalytic Performance):

Glassy carbon electrode polishing and cleaning: a glassy carbon electrode is polished and cleaned step by step with alumina polishing powder with different particle sizes (such as particle size of 1, 0.3, or 0.05 μm), the surface of the glassy carbon electrode is cleaned with a large amount of ultrapure water after each stage of polishing, residual alumina powder is removed by ultrasound for 30 s, and the glassy carbon electrode is dried by nitrogen gun for later use.

Slurry preparation: a mixed solution of 5 mg catalyst (carbon materials prepared in different Examples), 550 μL ultrapure water, 400 μL isopropanol, and 50 μL Nafion (5 wt. %) is ultrasonically dispersed at a constant temperature of 20° C. for 60 min.

Working electrode preparation: 10 μL of catalyst slurry is added dropwise to the surface of glassy carbon electrode with an area of 0.2475 cm², and naturally air-dried.

Oxygen saturated electrolyte configuration: 4 g of sodium hydroxide is accurately weighed and dissolved in 1 L of ultrapure water with stirring, high-purity oxygen is introduced, and this is continued for 30 min until the dissolved oxygen in the electrolyte reaches saturation.

### Electrochemical Test:

100 mL of oxygen saturated electrolyte is taken and placed in a five-necked reaction flask, and high-purity oxygen is continuously pumped into the flask during the test. A graphite rod is used as a counter electrode, and a mercury/mercuric oxide electrode is used as a reference electrode. Firstly, 100 cycles of cyclic voltammetry tests are performed until the electrode surface reaches a quasi-steady state; and polarization curve tests are performed (a ring electrode oxidation voltage is fixed at 1.2 V vs RHE, and an electrode rotation speed is 1600 rpm). The polarization curves need to be measured repeatedly until the polarization curves completely overlap; and the electrolyte needs to be replaced for each sample change test.

### 2. Two-Electrode Flow-Through Electrolyzer Test (for Evaluating Catalyst Activity and Stability Under High Current)

### Gas Diffusion Electrode Preparation:

Slurry preparation: 80 mg of catalyst (carbon materials prepared in different Examples), 4 mL of ultrapure water, 3.2 mL of ethanol, 0.8 mL of aqueous polytetrafluoroethylene solution (5 wt. %) are ultrasonically dispersed at a constant temperature of 20° C. for 60 min.

Electrode preparation: the catalyst slurry is uniformly loaded onto a central area (2×2 cm²) of a carbon paper (with the carbon paper size being 3×3 cm²) using ultrasonic spraying technology; and the catalyst loading is 4 mg/cm².

Electrolyte configuration: 500 g of sodium hydroxide is accurately weighed and dissolved in 5 L of ultrapure water with stirring.

Electrochemical test: a 2×2 cm² commercial nickel foam is used as the anode; the cathode is a self-made gas diffusion electrode. A side of the carbon paper sprayed with the catalyst is in contact with the electrolyte, and a back (the other side) of the carbon paper is in direct contact with air (air is served as the oxygen source for the oxygen reduction reaction). The cathode/anode chambers are separated by a commercial proton membrane; and a distance between the cathode and anode electrodes is 2 mm.

The prepared 5 L electrolyte is poured into an anode liquid storage tank, and 5 L of ultrapure water is added into a cathode liquid storage tank at the same time. A constant temperature water bath is turned on, and a temperature of the electrolyte storage tank is controlled at 20° C. A peristaltic pump is turned onto fill the cathode chamber and anode chamber with water and electrolyte, respectively; both flow rate of cathode chamber and flow rate of anode chamber are 20 mL/min. After the electrodes are connected, an electrochemical workstation is turned on, and a constant current electrolysis test is conducted at a current density of 300 mA/cm² (anode reaction: 2NaOH→1/2O₂+H₂O+2Na⁺2e⁻; and cathode reaction: O₂+2H₂O+2Na⁺2e⁻→H₂O₂+2NaOH). The concentration of hydrogen peroxide in the cathode chamber is measured every 10 h; and the concentration of hydrogen peroxide in the cathode electrolyte is determined by the potassium titanium oxalate spectrophotometric method.

### Test Results

TABLE 2
Orthogonal experimental results of PECVD oxygen
doped carbon materials in Examples 1-9

| | | | | Electrocatalytic | |
|---|---|---|---|---|---|
| | | | | activity | |
| Experiment | | | | half-wave | H₂O₂ |
| number | Atmosphere | Temperature/° C. | Power/W | potential/V | Selectivity % |
| Example 1 | O₂/Ar | 25 | 100 | 0.652 | 90 |
| Example 2 | O₂/Ar | 100 | 500 | 0.673 | 92 |
| Example 3 | O₂/Ar | 200 | 300 | 0.712 | 95 |
| Example 4 | CO₂/Ar | 25 | 500 | 0.661 | 90 |
| Example 5 | CO₂/Ar | 100 | 300 | 0.684 | 93 |
| Example 6 | CO₂/Ar | 200 | 100 | 0.725 | 96 |
| Example 7 | H₂O/Ar | 25 | 300 | 0.643 | 86 |
| Example 8 | H₂O/Ar | 100 | 100 | 0.651 | 85 |
| Example 9 | H₂O/Ar | 200 | 500 | 0.656 | 88 |

Range analysis

| | | | |
|---|---|---|---|
| Item | Atmosphere | Temperature | Power |

Catalyst activity→half-wave potential/V

| | | | | |
|---|---|---|---|---|
| K1 | 0.679 | 0.652 | 0.676 | |
| K2 | 0.690 | 0.669 | 0.680 | |
| K3 | 0.650 | 0.698 | 0.663 | — |
| R | 0.040 | 0.046 | 0.017 | |

Catalyst selectivity→H₂O₂ selectivity %

| | | | |
|---|---|---|---|
| K1 | 92.3 | 88.7 | 90.3 |
| K2 | 93 | 90 | 88 |
| K3 | 86.3 | 93 | 90 |
| R | 3.3 | 4.3 | 2.3 |

From the range analysis R value in Table 2, it can be seen that the atmosphere and reaction temperature in the PECVD reaction are the most important factors affecting the electrocatalytic activity and selectivity of oxygen-doped carbon materials, while the plasma RF power has little impact on the catalyst performance. From the average value of K, the most preferable atmosphere is to be CO₂/Ar, the most preferable reaction temperature is to be 300° C., and the most preferable RF power is to be 100 W.

The “initial carbon” mentioned below refers to the carbon black used in the Examples (XC-72R, Cabot Corporation).

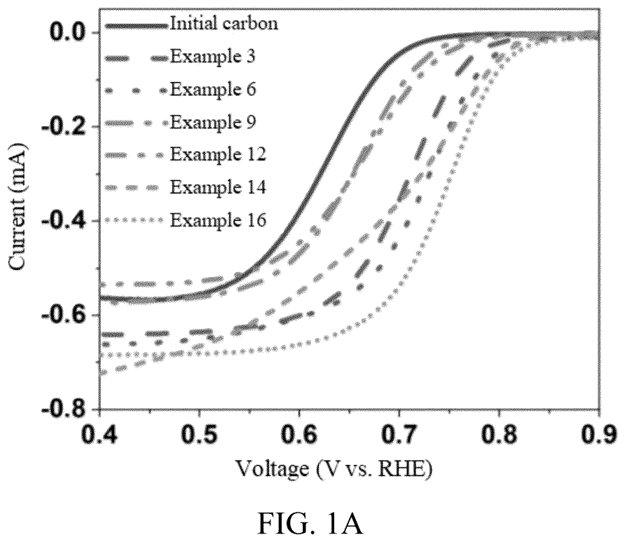

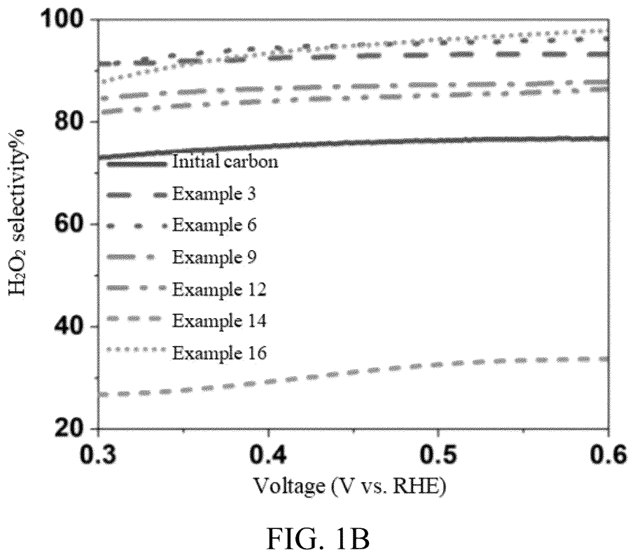

FIG. 1A shows oxygen reduction polarization curves of different carbon materials; and FIG. 1B shows hydrogen peroxide selectivity curves of different carbon materials. It can be seen from FIGS. 1A and 1B that oxygen doping can significantly improve the electrocatalytic activity for oxygen reduction and hydrogen peroxide selectivity of carbon materials. However, due to differences in preparation process parameters, the electrocatalytic performance of the oxygen-doped carbon materials obtained in Examples 3 and 6 is much higher than that of the oxygen-doped carbon material prepared in Example 9. Compared with oxygen doping, nitrogen doping has a relatively weaker enhancement effect on carbon materials (Examples 12 and 14). However, oxygen-nitrogen co-doping (Example 16) exhibits the optimal electrocatalytic activity for oxygen reduction and hydrogen peroxide selectivity. This indicates that oxygen or nitrogen doping has a synergistic effect, which can further improve the electrocatalytic performance of oxygen-doped carbon materials.

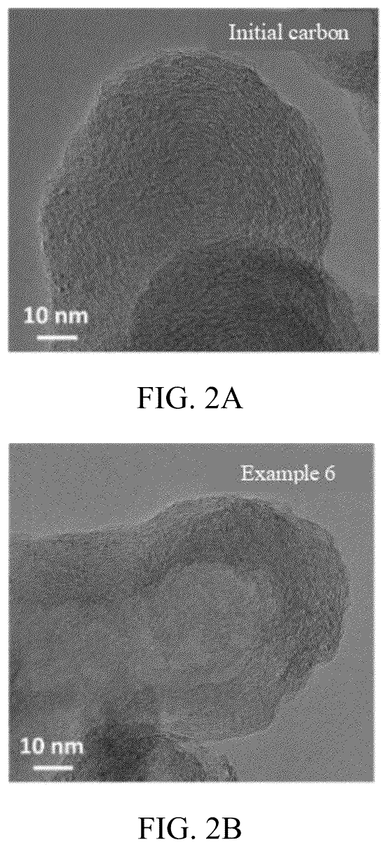

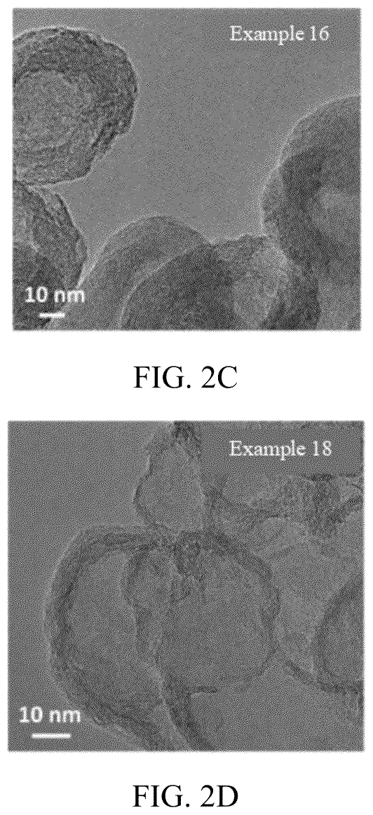

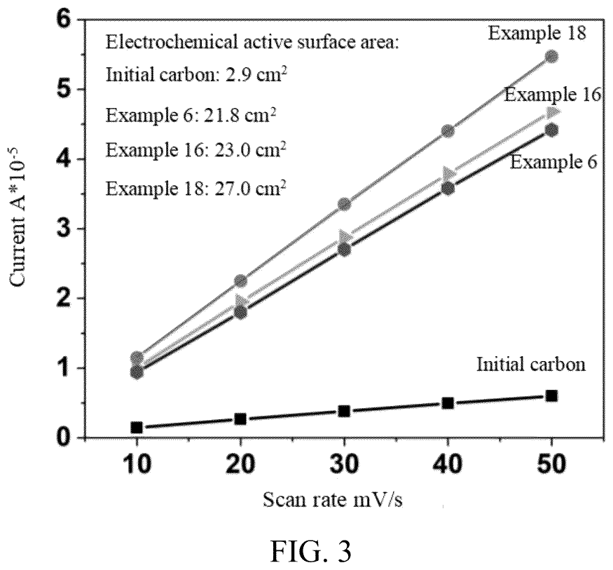

FIGS. 2A-2D show TEM images of different carbon materials. It can be seen from FIG. 2B, after the carbon nanoparticles are treated with carbon dioxide plasma (Example 6), the number of graphite layers is significantly reduced, and hollow carbon nanoparticles are formed. This is because carbon dioxide produces a large amount of active oxygen free radicals and CO free radicals after radiofrequency excitation, which produce a violent ablation reaction with the carbon surface in a high-temperature environment to generate gases including carbon dioxide or carbon monoxide, resulting in the thinning of the graphite layer. The formation of this special structure is conducive to increasing the electrochemical active specific surface area (FIG. 3), strengthening the mass transfer process of oxygen reduction reaction, and improving the electrocatalytic performance of oxygen-doped carbon materials.

XPS is used to reveal the intrinsic relationship between the catalytic performance of various oxygen-doped carbon materials and the geometric configurations of doped oxygen in these materials.

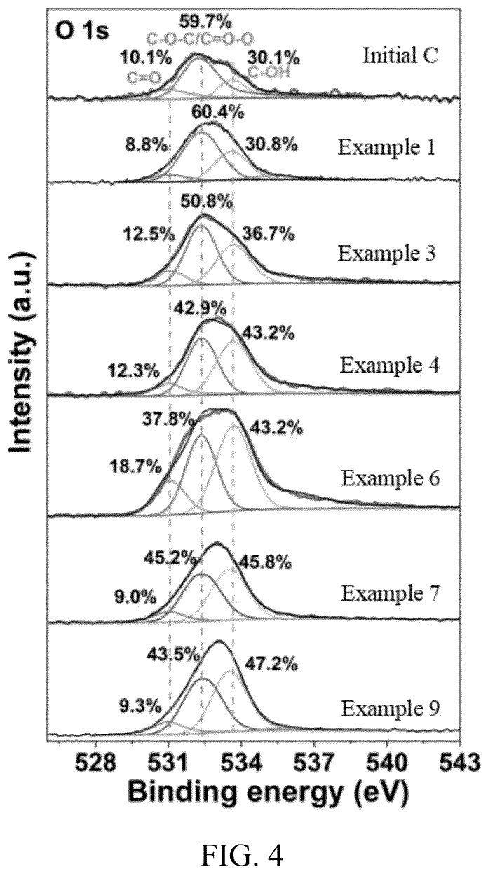

FIG. 4 shows high-resolution Ols XPS spectra of different carbon materials. It can be seen from the high-resolution Ols XPS spectra in FIG. 4 that compared with the oxygen-doped samples at room temperature, the content of carbonyl C═O (BE=531.0 eV) in the samples treated at 300° C. is significantly increased. Moreover, the content of carbonyl C═O generated by the carbon dioxide plasma source is relatively higher than that of the oxygen/water plasma treatment. This is because the C═C double bonds in carbon materials are relatively active and are easily attacked by oxygen plasma to generate C—O bonds. The hydrogen atom is transferred from the adjacent chain to bond to the C—O bond to produce the C—OH bond. In addition, under the action of oxygen plasma, various other oxygen configurations can be formed through intramolecular recombination, including carboxyl oxygen, ester oxygen, ether oxygen and carbonyl oxygen. Compared with oxygen excitation, carbon dioxide excitation can produce a large amount of oxygen plasma and CO plasma. Therefore, in addition to the above interaction between oxygen plasma and carbon materials, CO plasma may form carbonyl groups in C—C—C═O configuration with broken C═C bonds, resulting in relatively high carbonyl oxygen in carbon materials treated with carbon dioxide plasma.

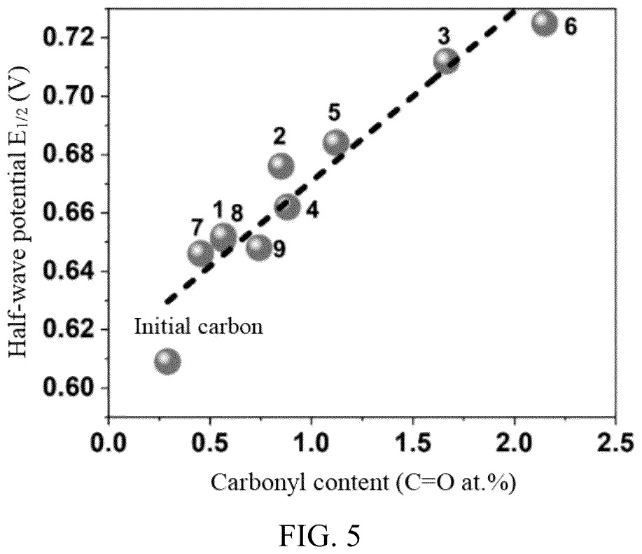

FIG. 5 shows a relationship diagram between carbonyl content and electrocatalytic activity of the initial carbon material and the oxygen-doped carbon materials prepared in Examples 1-9. It can be seen from FIG. 5 that the activity of oxygen-doped carbon materials shows a significant positive correlation with the carbonyl C═O content (linear relationship between half-wave potential E_{1/2} and carbonyl content: y=0.058×+0.61, R²=0.90). The above experimental results show that under relatively high temperature environment and carbon dioxide atmosphere, it is more conducive to the introduction of carbonyl C═O, which is helpful to obtain highly active and selective oxygen-doped carbon materials.

It can be concluded that the high performance of oxygen-doped carbon materials mainly comes from the special hollow nanoparticle structure and the high carbonyl oxygen content with high catalytic activity.

TABLE 3
Electrocatalytic activity and selectivity of nitrogen-
doped carbon materials in Examples 10-14

| | | | | Electrocatalytic | |
|---|---|---|---|---|---|
| Experiment | | | | activity half-wave | H₂O₂ |
| number | Atmosphere | Temperature/° C. | Power/W | potential/V | Selectivity % |
| Example 10 | N2 | 25 | 100 | 0.658 | 86 |
| Example 11 | N2 | 25 | 300 | 0.653 | 82 |
| Example 12 | N2 | 25 | 500 | 0.661 | 84 |
| Example 13 | N2 | 100 | 500 | 0.672 | 75 |
| Example 14 | N2 | 200 | 500 | 0.698 | 29 |

It can be seen from Table 3 that PECVD power has a weak effect on the electrocatalytic activity of nitrogen-doped carbon materials. However, with the increase of PECVD reaction temperature, the electrocatalytic activity of nitrogen-doped carbon materials is significantly enhanced. It is worth noting that while the activity increases, hydrogen peroxide selectivity of nitrogen-doped carbon materials decreases.

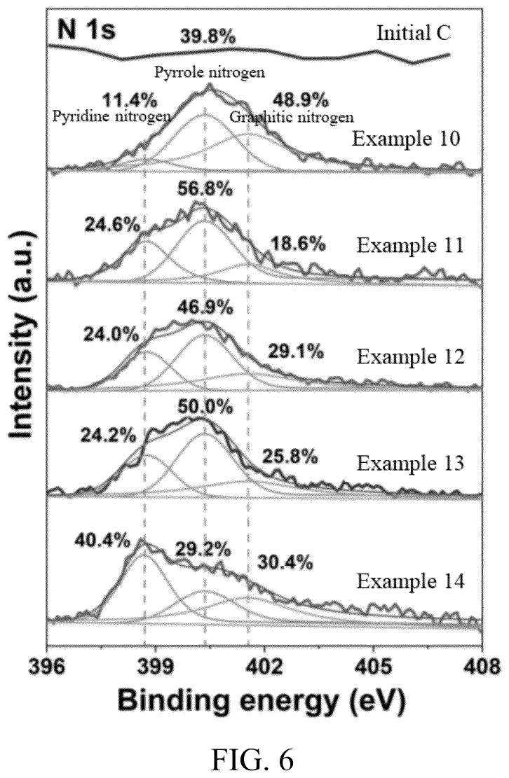

FIG. 6 shows high-resolution Nis XPS spectra of different carbon materials. The XPS results in FIG. 6 show that nitrogen atoms have been successfully introduced into the crystal lattice of carbon materials. At room temperature, nitrogen atoms mainly exist in configurations of pyridine nitrogen and pyrrole nitrogen, and an atomic ratio of pyridine nitrogen to pyrrole nitrogen is approximately 0.5. However, with the reaction temperature rising to 300° C., the atomic ratio of pyridine nitrogen to pyrrole nitrogen increased to 1.3, indicating that the content of pyridine nitrogen increased greatly. The above experimental results show that nitrogen doping can effectively improve the electrocatalytic activity of carbon materials, and increasing the content of pyridine nitrogen is more beneficial to the electrocatalytic activity of carbon materials. However, the hydrogen peroxide selectivity of carbon materials is reduced due to increasing the content of apyridine nitrogen.

In the present disclosure, after determining the geometric relationship between each process parameter and the introduced oxygen/nitrogen, the oxygen/nitrogen atom co-doped carbon material with a specific geometric configuration is synthesized, and nitrogen atoms are introduced into the crystal lattice of the oxygen-doped carbon material to synthesize the oxygen-nitrogen co-doped hollow carbon nanoparticles (Examples 15-18). The results are shown in Table 4.

TABLE 4
Electrocatalytic activity and selectivity of oxygen-nitrogen co-doped hollow carbon nanoparticles in Examples 15-18

| | Atmosphere | | Temperature/° C. | | Power/W | | Time/min | | Electrocataly-tic | H₂O₂ |
|---|---|---|---|---|---|---|---|---|---|---|
| | Oxygen | Nitrogen | Oxygen | Nitrogen | Oxygen | Nitrogen | Oxygen | Nitrogen | activity | selectivity |
| Number | doping | doping | doping | doping | doping | doping | doping | doping | E_{1/2} V | % |
| Example | CO₂/ | N2 | 200 | 25 | 100 | 500 | 10 | 10 | 0.734 | 97 |
| 15 | Ar | | | | | | | | | |
| Example | CO₂/ | N2 | 200 | 200 | 100 | 500 | 10 | 10 | 0.741 | 96 |
| 16 | Ar | | | | | | | | | |
| Example | CO₂/ | N2 | 200 | 200 | 100 | 500 | 20 | 10 | 0.745 | 93 |
| 17 | Ar | | | | | | | | | |
| Example | CO₂/ | N2 | 200 | 200 | 100 | 500 | 20 | 40 | 0.743 | 95 |
| 18 | Ar | | | | | | | | | |

It can be seen from Table 4 and FIGS. 1A and 1, the oxygen-nitrogen co-doped hollow carbon nanoparticles have higher electrocatalytic activity and exhibit considerably higher hydrogen peroxide selectivity than single oxygen doping (Example 6) or nitrogen doping (Example 14). It is worth noting that increasing the nitrogen doping reaction temperature is beneficial to obtain more active oxygen-nitrogen doped carbon materials (as shown in Table 4). However, with increasing the duration of oxygen doping reaction, the electrocatalytic performance of oxygen-nitrogen co-doped hollow carbon nanoparticles remains basically unchanged (as shown in Table 4). This may be because after increasing the oxidation time, the introduced oxygen content has reached the upper limit, which will not produce more active sites, but will aggravate the thinning process of the graphite layer (Example 18, FIG. 2D).

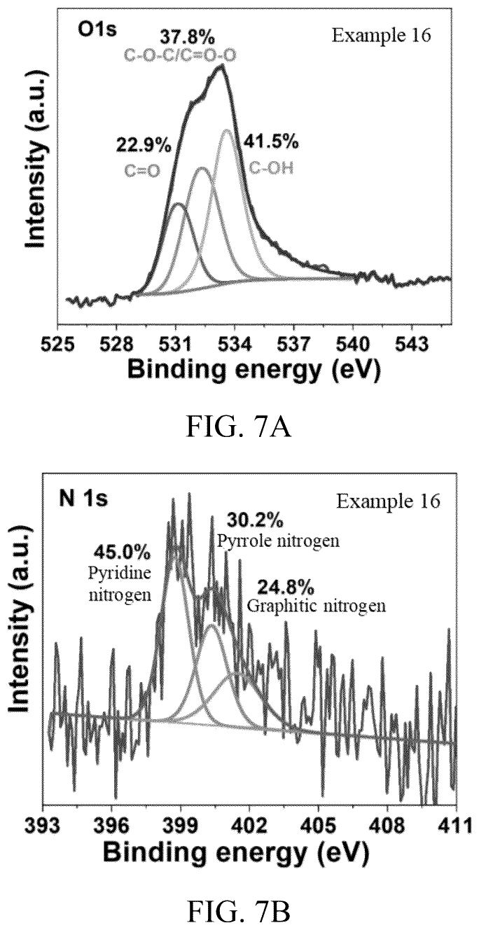

FIG. 7A shows a Ols spectra of oxygen-nitrogen co-doped hollow carbon nanoparticles prepared in Example 16; and FIG. 7B shows a N1s spectra of the oxygen-nitrogen co-doped hollow carbon nanoparticles prepared in Example 16. It can be seen from FIGS. 7A and 7B that the geometric configuration of oxygen atoms (FIG. 7A) and geometric configuration of nitrogen atoms (FIG. 7B) in the oxygen-nitrogen co-doped hollow carbon nanoparticles are basically consistent with those of the materials in Example 6 and Example 14, and this consistency ensures that these oxygen-nitrogen co-doped hollow carbon nanoparticles have excellent intrinsic electrocatalytic performance.

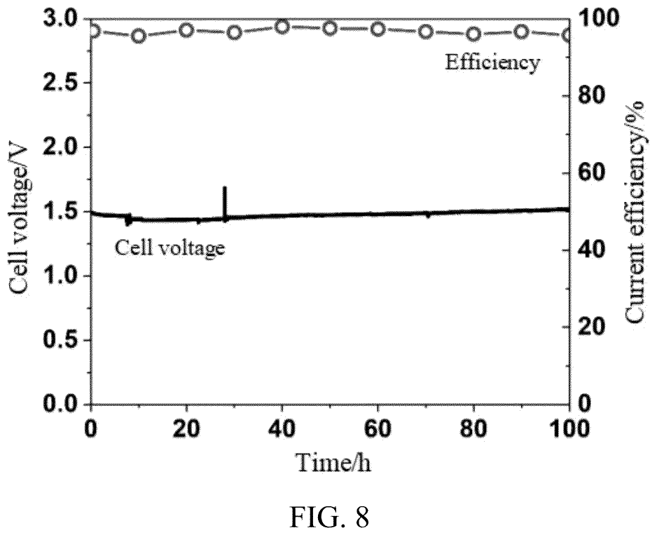

FIG. 8 shows a graph of cell voltage and hydrogen peroxide selectivity versus time in the oxygen-nitrogen co-doped hollow carbon nanoparticles prepared in Example 16. It can be seen from FIG. 8 that under the constant current test with high current density (such as 300 mA/cm²), the cell voltage of the electrolyzer is basically stable, and the selectivity of hydrogen peroxide can be maintained at approximately 95%. This indicates that the oxygen-nitrogen co-doped hollow carbon nanoparticles of the present disclosure have excellent electrocatalytic activity for two-electron oxygen reduction, hydrogen peroxide selectivity, and stability.

The above-mentioned examples are only the preferred examples of the present disclosure, it is to be pointed out that for those ordinary skilled in the art, several improvements and embellishments can be made without departing from the principle of the present disclosure, and these improvements and embellishments are also regarded as the protection scope of the present disclosure.

1. A preparation method for an oxygen-nitrogen co-doped hollow carbon nanoparticle, comprising the steps of:
adopting a plasma-enhanced chemical vapor deposition (PECVD) method:
performing a first deposition on carbon nanoparticles in an oxygen-containing atmosphere, and obtaining oxygen-doped hollow carbon nanoparticles through ablation effect of oxygen-containing plasma; and
performing a second deposition on the oxygen-doped hollow carbon nanoparticles in a nitrogen-containing atmosphere to obtain oxygen-nitrogen co-doped hollow carbon nanoparticles, wherein a surface graphite layer of the oxygen-nitrogen co-doped hollow carbon nanoparticles has a thickness of 5-100 atomic layers, and a cavity width of 5-50 nm;
in the oxygen-nitrogen co-doped hollow carbon nanoparticles, a molar content of doped oxygen atoms is 1-12%, and a molar content of carbonyl oxygen atoms in the doped oxygen atoms in the oxygen-nitrogen co-doped hollow carbon nanoparticles is 0.5-3%; and the carbonyl oxygen has an X-ray photoelectron spectroscopy (XPS) binding energy (BE) BE=531.0 eV;
a content x of the carbonyl oxygen atoms and an electrocatalytic activity y satisfy following functional relationship: y=0.058x+0.61, with R²=0.90; where y is calculated by a half-wave potential E_{1/2} in volts (V) versus (vs.) a reversible hydrogen electrode (RHE);
in the oxygen-nitrogen co-doped hollow carbon nanoparticles, a molar content of doped nitrogen atoms is 14%, a molar percentage of pyridine nitrogen and pyrrole nitrogen in the doped nitrogen atoms is 50-80%, and a molar ratio of the pyridine nitrogen and the pyrrole nitrogen is 0.5:1-2:1;
the oxygen-containing atmosphere comprises one or more of oxygen-argon, carbon dioxide-argon, or water vapor-argon;
the nitrogen-containing atmosphere comprises nitrogen or ammonia; and
conditions of the first deposition and the second deposition independently comprise: plasma radio frequency (RF) power of 100-500 W, vacuum degree of 10-100 Pa, sample tube rotation speed of 50-100 rpm, temperature of 300-500° C., and time of 10-60 min.

2. The preparation method according to claim 1, wherein the carbon nanoparticles are conductive carbon black, and a particle size of the conductive carbon black is 10-200 nm.

3. The preparation method according to claim 1, wherein a volume fraction of argon in the oxygen-containing atmosphere is 50-90%; and a flow rate of the oxygen-containing atmosphere is 20-200 mL/min.

4. The preparation method according to claim 1, wherein a flow rate of the nitrogen-containing atmosphere is 20-200 mL/min.

5. An oxygen-nitrogen co-doped hollow carbon nanoparticle prepared by the preparation method according to claim 1.

6. An oxygen-nitrogen co-doped hollow carbon nanoparticle prepared by the preparation method according to claim 2.

7. An oxygen-nitrogen co-doped hollow carbon nanoparticle prepared by the preparation method according to claim 3.

8. An oxygen-nitrogen co-doped hollow carbon nanoparticle prepared by the preparation method according to claim 4.

9. An application of the oxygen-nitrogen co-doped hollow carbon nanoparticle according to claim 5 in electrosynthesis of hydrogen peroxide.

10. An application of the oxygen-nitrogen co-doped hollow carbon nanoparticle according to claim 6 in electrosynthesis of hydrogen peroxide.

11. An application of the oxygen-nitrogen co-doped hollow carbon nanoparticle according to claim 7 in electrosynthesis of hydrogen peroxide.

12. An application of the oxygen-nitrogen co-doped hollow carbon nanoparticle according to claim 8 in electrosynthesis of hydrogen peroxide.
